(19) United States
(12) Patent Application Publication
(10) Pub. No.: US 2008/0056504 A1
(43) Pub. Date: Mar. 6, 2008

(54) Dynamic Range Control Of An Audio Signal And Method Of Its Operation

(76) Inventors: Frederik Gorges, Bochum (DE); Wolfgang Edeler, Vreden (DE)

Correspondence Address: Hollingsworth & Funk, 8009 34th Avenue South, Suite 125, Minneapolis, MN, 55425, US

(21) Appl. No.: 10/560,675

(22) PCT Filed: Jun. 18, 2003
(86) PCT No.: PCT/IB03/02351

§ 371 Date: Feb. 23, 2007

(51) Int. Cl. H03G 11/00; H03G 3/00

(52) U.S. Cl. 381/55; 381/104

(57) ABSTRACT

The present invention relates to electric audio devices and to communication devices. It also relates to the protection and increased performance of audio devices and electro acoustic 5 transducers like loudspeakers and headphones in portable devices and fixed installed equipment in entertainment products. The present invention provides a method for operating a dynamic range control with an adaptive threshold. A dynamic range control comprises at least an audio signal input, an audio signal output and a power or volume control. The method comprises receiving a number of thresholds comprising at least a maximum power level for short time interval operation and a maximum power level for long time operation of an electro acoustic transducer. The method further comprises continuously detecting the power of the audio input signal. The method further short term controls the power of the output signal in a way that the power of the output signal is reduced in a way that it substantially equals said maximum power level for short time operation, in case that the detected power of said audio signal input exceeds said maximum power level for short term interval operation. The method further long term controls the power of the output signal in a way that the power of the output signal is reduced until it substantially equals said maximum power level for long time operation, if the determined power of said audio signal exceeds said maximum power level for long time operation, for at least a predetermined period of time. That is if this period of time is exceeded the long term control is operated, whereas if the time period is not attained only short time control as above is operated.

The present invention relates to electric audio devices and to communication devices. It also relates to the protection and increased performance of audio devices and electro acoustic transducers like loudspeakers and headphones in portable devices and fixed installed equipment in entertainment products. More specifically the invention relates to electronic devices that generate an analog audio output signal from digital audio data.

Former approaches to protect electro acoustic transducers included e.g. a fixed maximum volume so that the output level from the amplifier cannot reach the physical limits of the electro acoustic transducer which when exceeded would damage the device. This approach results in not enough loudness and too much unused headroom of the electro acoustic transducer. Another drawback resides in the fact that the employment of devices having exchangeable headsets with different specifications may lead to unsuitable headset device combinations.

Another possibility is to use dynamic range controllers (DRC) as a slow volume regulation to prevent overload for transducer without signal dynamic compression, which results in reduced loudness.

The state of the art knows many different electronic audio devices. One suggestion to protect devices from overload and users from an excessively loud audio signals via a headset is described in the U.S. Pat. No. 4,928,307 titled “Time dependent, variable amplitude threshold output circuit for frequency variant and frequency invariant signal discrimination”.

This document discloses a volume control in case of music reproduction in telephones and music devices that can be operated with headsets. The document deals with the problem, that an output signal should not exceed a threshold for a longer time interval even in case of a fluctuating input signal, to prevent that the listening user may be uncomfortable because of the high signal level.

The document suggests a back bias approach, wherein the output signal is evaluated with the help of a comparator and a threshold/reset timer. When the signal exceeds a determined threshold, the amplification factor is decreased. When the signal exceeds a determined threshold for more than a pre-determined time interval, the amplification factor is decreased in a following second step.

This implementation shows two disadvantages:

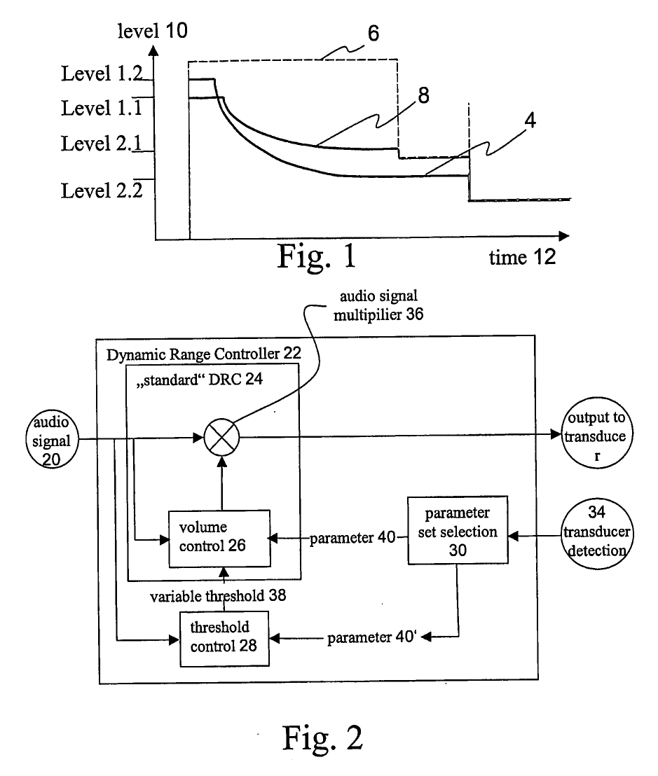

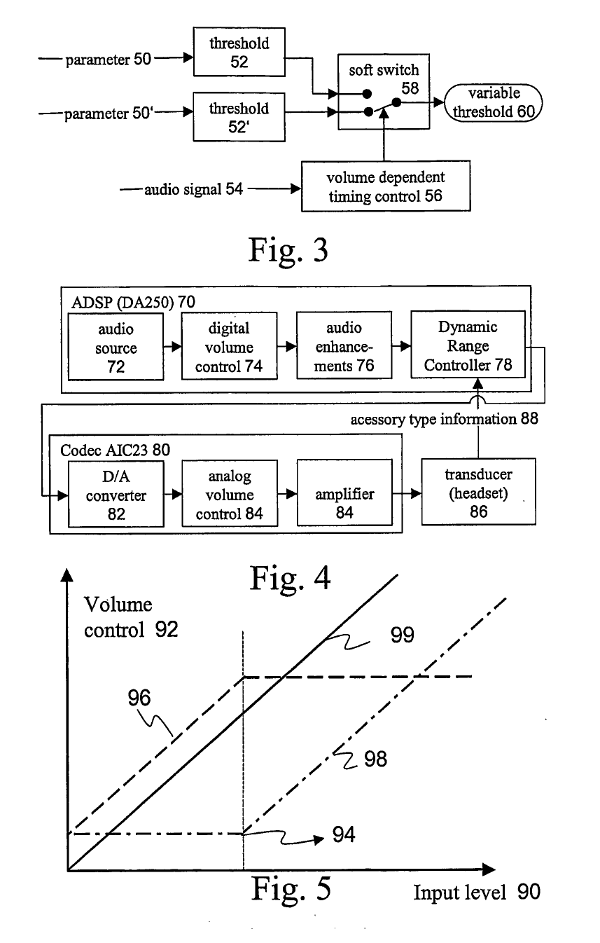

1. By using back bias and an analog-only implementation of the volume control, the reaction time for reducing of the amplification factor may be relatively high. This can be derived from the occurrences of signal peaks (see e.g. FIG. 1B and FIG. 3 ‘acoustic output’). These peaks may be acceptable in case of audio voice transmissions but in the case of music, these peaks would be noticeable by the user as distorted dynamics.

2. In the US document, the amplification ratio reduces in a “hard manner” upon exceeding a predefined level in the audio output signal. That is the level of the audio output signal is suddenly decreased or increased for several dB. Although such a control characteristic may be acceptable in the case of audio voice signals, but not in case of music signals.

It is thus desirable to have an automatic volume or power control that is capable to protect electro acoustic transducers as loudspeakers and headphones from overload, thermal and mechanical damage.

It is further desirable to improve the volume or power control of the state of the art, to enable such a system to be applied to music audio signals.

It is also useful to have means at hand to protect the organ of hearing of a user of headsets of communication and sound replay devices from detrimental sound.

It is desirable to improvingly control the power or volume control to protect electro acoustic transducers from overload, thermal and mechanical damage.

It is also desirable to optimize the power capacity and the signal to noise ratio in the signal path of digital audio devices for producing maximum acceptable loudness.

According to a first aspect of the present invention, there is provided a method for operating a dynamic range control with an adaptive threshold. A dynamic range control comprises at least an audio signal input, an audio signal output and a power or volume control. The method comprises receiving a number of thresholds comprising at least a maximum power level for short time interval operation and a maximum power level for long time operation of an electro acoustic transducer.

The method further comprises continuously detecting the power of the audio input signal.

The method further short term controls the power of the output signal in a way that the power of the output signal is reduced in a way that it substantially equals said maximum power level for short time operation, in case that the detected power of said audio signal input exceeds said maximum power level for short term interval operation.

The method further long term controls the power of the output signal in a way that the power of the output signal is reduced until it substantially equals said maximum power level for long time operation, if the determined power of said audio signal exceeds said maximum power level for long time operation, for at least a predetermined period of time. That is if this period of time is exceeded the long term control is operated, whereas if the time period is not attained only short time control as above is operated.

Said long term control overrides said short term control. This is the long term control takes the lead if both controls are interfering.

It may be noted that in specification and in the claims the expression ‘volume control’, ‘amplification’ and ‘attenuation’ are synonymously used to describe a signal processing of the power level of a signal. Similarly the expressions ‘signal strength’, ‘loudness’, ‘signal power’ and ‘power level’ are uses similarly to refer to an amplitude of a audio signal or more exactly to the electrical signal that can be converted into an acoustic signal when supplied to an electro acoustic transducer.

In addition, the expressions ‘power’, ‘volume’ and ‘signal strength’ are synonymously used in the following text. The expression ‘substantially equals’ has been chosen in the specification to underline that the signal level is normalized to the highest possible output level without exceeding the short time and long time power requirements of the electro acoustical transducers. The expression ‘substantially equals’ is also chosen to emphasize that equality is to be considered to be within reasonable technological limits (considering even low cost electronic audio devices).

The at least two thresholds can be received automatically, e.g. by an automated recognition of the connected electro acoustic transducer, or e.g. by respective user input selected e.g. via a respective menu setting. The at least two thresholds may be extended e.g. by a maximum power level for mid time operation, or respective time intervals defining the “short time interval”, “mid time interval” or “long time”. It may be noted that the maximum power level for short time operation is usually higher than the maximum power level for long time operation.

The method further comprises continuously detecting the power of the audio input signal. The power level of the signal can be determined anywhere within the signal path, as all the signal strengths are related by known amplification or attenuation factors. As the amplification factors are known to the system, the system can derive the actual output level independently from the point the signal power is measured and thus determined. The closer to the source the signal strength is determined the earlier the short term control can reduce too high levels, but the more amplification factors have to be taken into account and vice versa. It may be noted that the signal strength can be determined upstream and downstream of the dynamic range control (DRC), wherein the upstream value may be preferred in the short term control algorithm of the maximum short time power, and a back bias control or a forward control can be used for the long term control algorithm of the maximum long time power.

By short term controlling the volume of the signal in a way that the power of the output signal equals said maximum power level for short time operation, it is assured that the output power is not over-attenuated. So short signals can be outputted with maximum possible power. This short term control algorithm may be described as a fast normalizing of the high output power levels to the maximum short time interval power level of the electro acoustical transducer. This short term control is to be performed relatively fast.

By long term controlling the volume of the signal by reducing the power of the output signal to said maximum power level for long time operation, it is assured that the output power can not damage the. electro acoustical transducer by operating an excessively long time with maximum short time operation power. Long signals can be outputted with maximum possible power. This long term control algorithm may be described as a (slow) normalizing of the too high output power levels to the maximum long time interval power level of the electro acoustical transducer. By ‘normalizing’ the power level in a timer controlled way it can be assured that the output power is not over-attenuated. This long term second algorithm may be provided with a kind of soft switch, to prevent that the transition from the maximum short time interval power level to the maximum long time power level produces perceivable distortions in the signal.

So basically the method can be described by the combination of two sub-algorithms: a fast reacting function to reduce strong signals to the maximum short time output power followed by a slow reacting adaptation of the signal to the maximum long time output power.

The short term control algorithm reduces too strong signals to the maximum short time output power, which may be described as a power reduction to the maximum short time output power. The long term control algorithm reduces too strong signals to the maximum long time output power in a time controlled manner, which may be described as a timer controlled power cutoff to the maximum long time output power. Both control algorithms can be regarded as being operated independently. In case of short and high power input signals only the short term control algorithm will be activated. In case of long and intermediate power input signals (i.e. signals having a power in between said two thresholds) both the short term and the long term control algorithm will be activated and mixed using the soft switch. In case of long and high power input signals first the short term control algorithm will be activated, and the long term control algorithm will be activated later, overriding said short term control.

Therefore, the method of the present invention can provide a maximum output level for audio amplifiers, that is dependent on the connected electro acoustic transducer and that is time dependent. The adaptable maximum output levels for audio amplifiers provide a thermal limitation and mechanical protection for the electro acoustic transducer by using dynamic compression (attenuation) to increase the power and loudness capacity, reduce the unused power headroom and limit the maximum loudness for safety requirements.

The method may be extended by a determination of the time period in which said output signal is operating at a power above said power level for long time operation. This may be implemented as a dedicated timer element in the method, so the method may be extended actions like starting a timer, and activating said long term controlling of the power upon the runoff of said timer. Alternatively, the timer may additionally be activated with the activation of said short time power normalization.

A timer element of the maximum power level for long time operation may be coupled with an integrator element, to ensure that high power signals interrupted by shorter low power intervals can not get past the maximum power level for long time operation. With such an ‘integrator element’ the electro acoustic transducer may be protected from ‘short periodic high duty cycle signals’.

Instead of a timer element, an integrator element can be used to activate said long term power control algorithm. By using an integrator element the expected amount of energy that is deposited in the electro acoustic transducer may be calculated which may be the main cause of damage of said transducer.

In another example embodiment of the present invention the speed said long term controlling of the of the signal power is performed depending from the difference power between said detected input signal and said maximum power level for long time operation. So the response of the second part of the algorithm may be related to a distance characteristic and to a time characteristic that depends on how distant the maximum power level for long time operation is exceeded. So small differences between the actual signal strength and maximum power level for long time operation will lead only to slow control speed to smoothly normalize the signal strength. In case of signals exceeding the maximum power level for long time operation the volume control would be performed with a constant time characteristic, which may be derived from the difference or the fraction of both thresholds.

The time characteristics may also be provided as a time threshold encoding the time characteristics of the second part of the method. A time threshold can represent a maximum time when the second algorithm has to be started. A time threshold can represent a maximum volume change rate within the second algorithm. A time threshold can represent a maximum change of the volume change rate within the second algorithm (second derivative).

In another example embodiment of said method, said thresholds are received from said electro acoustic transducer. The maximum power level for short time interval operation of the maximum power level for long time operation of an electro acoustic transducer can be provided from said electro acoustic transducer. The electro acoustic transducer can provide said data as the data or thresholds themselves or as a code number stored in a chip of said transducer.

In case of a headset a small chip in the earphone can be read out via a cable of a small transponder in e.g. a headphone plug, a mechanical interface, an earphone data card or the like. The data may also be downloaded from a homepage of a manufacturer of the electronic device.

In another preferred embodiment of the present invention said long term control comprises a smooth reduction of said output power level. This may be implemented by a hard wired or a soft switch.

In yet another example embodiment of the present invention said short term control comprises an immediate reduction of said output power level. This may be performed by a forward control instead of using a back bias control. So the input power level may be detected directly at the input and small time delays caused by signal processing may provide the time necessary to compensate the response time.

In another example embodiment said power control comprises a digital power controller having a digital control range and an analog power controller having an analog power control range. The power control is characterized in that said signal power is controlled analogously at signal levels lower than the control range of said analog control, and in that said signal power is controlled digitally at signal levels higher than the control range of said digital control, wherein the power control ranges of said analog and digital controls are not overlapping.

The power of the output signal is controlled analogously at lower volume levels and is controlled digitally at higher volume levels, wherein the power is controlled either analogously or digitally. Especially in audio devices having digital audio sources it may happen that the audio path can comprise a digital power control and an analog power control, wherein the digital one is usually placed upstream of the analog one. According to this embodiment, the analog only control is used to control the power in case of low power input signals, followed by a digital only control of the signal strength. Thereby it can be assured that the signal strength is held on the highest levels so that the signal to noise ratio of devices can be held on the highest values, as the signal strength is held on the highest possible level as long the signal is to be processed in the device.

To enable analog-digital power control without any perceivable transition, a small transition area wherein both analog and digital controls are active may be implemented to smudge the any differences in the power control characteristics of digital and analog power control. As long as the transition area is small with respect to the whole control range the whole application may be regarded as substantially transition-less.

According to yet another aspect of the invention, a software tool is provided comprising program code means for carrying out the method of the preceding description when said program product is run on a computer, a network device or an audio device.

According to another aspect of the present invention, a computer program product downloadable from a server for carrying out the method of the preceding description is provided, which comprises program code means for performing all of the steps of the preceding methods when said program is run on a computer, a network device or an audio device.

According to yet another aspect of the invention, a computer program product is provided comprising program code means stored on a computer readable medium for carrying out the methods of the preceding description, when said program product is run on a computer, a network device or an audio device.

According to another aspect of the present invention, a computer data signal is provided. The computer data signal is embodied in a carrier wave and represents a program that makes the computer perform the steps of the method contained in the preceding description, when said computer program is run on a computer, a network device or an audio device.

The method of the invention can be implemented as software in the digital signal processing area of a digital audio device. The present invention can also be implemented as a hardware implementation in the analog and/or the digital area of an audio device. The invention can e.g. be implemented in a cellular telephone, in an MP3-, CD-Player, in a digital radio and/or the like. The invention can be implemented as software for the detection of attached electro acoustic transducers and selecting electro acoustic transducer dependent parameters and thresholds for the operation of a signal (processing) path.

According to another aspect of the present invention a dynamic range controller with an adaptive threshold is provided that comprises at least an audio signal input, an audio signal output, means to continuously determine the power of the audio signal and a power controller.

The dynamic range control according to the present invention is characterized by means to receive at least two thresholds. The thresholds comprise at least a maximum power level for short time interval operation and a maximum power level for long time operation of an electro acoustic transducer.

The dynamic range control is further characterized by being configured to short term control the power of the audio signal output in a way that the power of the output is reduced to said maximum power level for short time operation, if the detected power of said audio signal input exceeds said maximum power level for short time interval operation. The described implementation of the present invention provides substantially the same advantages that have been discussed in the description of the method to operate the dynamic range control. This control stage may be implemented as a forward control.

The dynamic range control is further characterized by being configured to long term control the power of the audio signal output in a way that the power of the output signal is reduced to said maximum power level for long time operation, if the detected power of said audio signal input is exceeding said maximum power level for long time operation for a predetermined time period, wherein said long term control overrides said short term control. This control stage may be implemented as a forward control or as a back bias control.

The thresholds may be input or received as a dedicated user input or automatic recognition algorithm or an automated dynamic analyzing algorithm. The length of said “short interval” may also be retrieved as an additional parameter or threshold.

To determine the time interval in which the said maximum power level for long time operation is exceeded a timer element can be used to detect the period of time. The predetermined time should not exceed in the time interval that is identified as the ‘short time interval’ identified in the maximum power level for short time interval operation.

In another example embodiment said dynamic range control further comprises a soft switch to slowly control or reduce the power of the signal in a way that the power of the output signal equals said maximum power level. That is the transition from the maximum power level for short time interval operation to the maximum power level for long time operation can be performed in a smooth way. A soft switch can change the power level a controlled manner to prevent perceivable changes of the loudness in the output signal. The speed of changing (attenuating) the power level to the maximum power level for long time operation may be dependent on the how far the threshold is exceeded. In case that the threshold bas been exceeded by a huge amount the DRC responds by quickly changing the volume and in the case the threshold is only slightly exceeded the DRC responds only with small change rates of the volume.

In another example embodiment said dynamic range control according further comprises a timer element to operate said long term control in a timer controlled way.

According to another additional aspect the present invention provides an electronic audio device that comprises an audio signal source and an audio output, wherein said electronic device is characterized by a dynamic range control with an adaptive threshold as being described in the preceding description.

In a preferred embodiment said electronic audio device has a digital audio signal source and an analog audio output and that is characterized by a dynamic range control with an adaptive threshold according to the preceding description. The electronic audio device can be a mobile music player. The electronic audio device can be a (mobile or cellular) telephone. The electronic audio device can be a radio set. The electronic audio device can be a CD player. The electronic audio device can be an audio enabled computer. The electronic audio device can be HI-FI™ stereo audio system. The electronic audio device can be a combination of one of the above devices like a cellular music enabled telephone. The device can comprise none, one (Mono), two (stereo), three, four (Quattro), five (‘Dolby surround™’) or more loudspeakers.

A preferred embodiment of the present invention is characterized in that said audio source is a digital audio signal source and said audio output is an analog audio output. Thereby the invention can be applied to power or volume control elements in the digital and in the analog part of the signal path. The invention is related to the power or volume control in devices reproducing audio signals such as cellular phones that are supplied with e.g. a FM radio or a music player (MP3, AAC or the like).

In the field of power or volume controls it is important that the hardware connected to the output of the amplifier (different Earphones, Headsets, internal Loudspeakers, line in sockets of audio Recorders) are not overloaded. On the other hand care should be taken that the highest possible level can be outputted to assure that the audio signal (e.g. music) is not to played to quiet. A device implementing the present invention can readily fulfill all these demands.

In another example embodiment said electronic audio device according comprises means to receive at least two thresholds comprised in the dynamic range control with an adaptive threshold is that are implemented by an integrated circuit implemented in a connector of said electro acoustic transducer. Thereby, the actually connected transducer and said thresholds may be determinable in an automated way.

In the following, the invention will be described in detail by referring to the enclosed drawings in which:

FIG. 1 shows a diagram with the input signal and the resulting output signal according to one aspect of the present invention,

FIG. 2 shows an example of an implementation of a complete block diagram of the invention,

FIG. 3 shows one implementation of the threshold control from FIG. 2 in detail,

FIG. 4 shows an example of a signal path as a block diagram, and

FIG. 5 shows one implementation of the threshold control from FIG. 4 in detail to show the use of digital and analog power or volume controls.

FIG. 1 shows the input signal and the resulting output signal according to one aspect of the present invention. The diagram represents a signal level 10 at the y-axis and time 12 at the x-axis. The y-axis is provided with four levels, level 1.2, level 1.1, level 2.1, and level 2.2. The first number is indicative of the type of maximum output power long time or short time, and the second number is indicating the number of the transducer 1 or 2.

The level 1.1: equivalent to short term maximum output power of transducer #1, and the level 2.1: equivalent to long term (continuous) maximum output power of transducer #1. level 1.2: equivalent to short term maximum output power of transducer #2, and the level 1.1: equivalent to long term (continuous) maximum output power of transducer #2.

The interrupted line 6 represents the input signal and the lines 4 and 8 represent the DRC responses to the input signal 6.

In the input signal exceeds the maximum output powers of both transducers, and the respective DRCs respond with an immediate power or volume reduction to the respective maximum output powers (levels 1.2 and 1.1.). The immediate response can be implemented by a forward control.

After a certain time has passed both DRC respond with a decrease of the volume, as both signals exceed long term (continuous) maximum output power. In the example the power is slowly turned down to approach the respective long term (continuous) maximum output power of each of said transducers. The slow dragging control can be implemented by using a soft switch. A soft switch can slowly adjust the power until the desired output power is reached. The soft switch can be implemented with a linear, a progressive or even with an exponential characteristic.

The depicted signal is caused by a soft switch with an exponential characteristic. The soft switch continually changes the power, wherein the speed of switching is dependent on the actual distance between the signal and the long-term maximum output power.

In case of larger distance between the actual signal and the maximum output power level, the derivation of the signal is proportional to the actual distance between the signal and the desired power level.

It may be noted that the short term control and the long term control may be regarded as being operated independently. In case of e.g. short and high power input signals, only the short term control algorithm will be activated. In case of long and intermediate power input signals (i.e. signals having a power in between said two thresholds) only the long term control algorithm will be activated. In case of long and high power input signals first the short term control algorithm will be activated, and then the long term control algorithm will be activated, overriding said short term control. It may be noted that the short term control algorithm and the long term control algorithm may be implemented as completely independent control systems, wherein both control algorithms only control the same output element i.e. the power control.

FIG. 2 is an example of a possible implementation the present invention. The dynamic range controller (DRC) 22 comprises two inputs and one output. The DRC 22 has an audio signal input 20 and a transducer detection input 34. The DRC 22 has one output 32 for outputting the signal. In the present implementation of the DRC 22, a block 24 designates the standard functionality of conventional DRC. The conventional DRC uses a detected strength of the input signal 20 and a parameter (e.g. threshold 38 or parameter 40) to generate an output to an audio signal multiplier 36 to control the power of the output signal 32.

The present invention is implemented with a threshold control 28. The threshold control 28 detects the strength of the audio input signal 20 as one parameter to generate a variable threshold 38 that is used in this implementation to adapt the operation characteristics of the volume control 26 dynamically to the parameters 40′ selected 30 according to the connected transducer 34.

In contrast to the state of the art, different sets of parameters selected according to a respective electro acoustical transducer can be considered by varying the operation characteristics of the standard DRC 24 by the threshold control 28.

The kind of headset actually connected may be detected or identified by a headset-connector integrated IC, and the parameter 40′ for the identified headset may be retrieved form a database 30.

The implementation of the present invention is only illustrative, but not restricting. The elements 26 and 28 may be implemented in single functionality element. The parameter 40 may be economized. The elements 34 and 30 may be implemented in single functionality unit.

FIG. 3 shows one implementation of the threshold control 28 depicted in FIG. 2 in detail. The threshold control 28 comprises two thresholds 52 and 52′ that are generated or selected according to received parameters 50, 50′ (i.e. parameter 40′ in FIG. 2). The other input is the audio signal 54 (i.e. audio signal 20 in FIG. 2). Alternatively, the signal 54 may be an audio input signal-strength indicating signal. In the depicted implementation the volume dependent timing control 56 operates the soft switch 58 to smoothly provide the transition from the short term maximum output power (e.g. threshold 52′) to the long term (continuous) maximum output power (e.g. threshold 52).

The output threshold control 28 output a variable threshold 60 (i.e. variable threshold 38 in FIG. 2)

The outputted variable threshold 60 is continually controlled depending on the difference between actual input power level and the long term maximum output power level. The soft switch provides the transition from the short term maximum output power level long term maximum output power level, as depicted and disclosed in FIG. 1. Including the different possible transition functions disclosed in the description of FIG. 1.

In FIG. 4, a possible implementation of an audio-amplification path is depicted. The audio path can be divided in three sections

1. A digital signal path indicated by the ADSP 70 (application digital signal processor) e.g. a DA 250)

2. An analog signal path indicated by the Codec 80 (coder/decoder) e.g. a AIC23), and

3. The electro acoustical transducer 86

The digital signal path indicated (the ADSP 70) comprises an audio source 72, a digital volume control 74 an audio enhancement stage 76 and a DRC 78. All the signals within this block are digital signals.

The analog signal path indicated by the Codec 80 comprises a D/A (digital/analog) Converter 82 an analog volume or power control and the amplifier 84.

It can be seen in the figure that there is a digital volume control 74 upstream of the DRC 78 and an analog volume control 84 downstream of the DRC 78.

The DRC is connected to both volume controls to adjust the power of the output signal according to parameters or accessory type information 88 received from the transducer 86.

According to this embodiment an analog only control 84 is used to control the power in case of low power input signals, followed by a digital only control 74 of the signal strength. Thereby it can be assured that the signal strength between the elements 74 and 84 is held on the highest levels so that the signal to noise ratio (SNR) of the signal can be held on the highest possible values, as the signal strength is held on the highest possible level as long the signal is to be processed in the device (at the blocks 76 to 82). It is to be noted that the digital volume control 74 is not used as long as the analog volume control 84 can be or is used.

The block audio enhancements 76 can be implemented as an equalizer block a stereo widening block or a Dolby™ surround block, a bass boost block or the like, to e.g. improve or simulate a room acoustics of e.g. headsets.

FIG. 5 depicts a possible control characteristic of a volume control in case of an analog/digital volume control. The diagram presents a volume control 92 at the y-axis and input level 90 at the x-axis. The diagram comprises an analog control characteristic indicated by the interrupted line 96, a digital control characteristic indicated by the interrupted/dotted line 98 and an overall control characteristic indicated by the line 99. At low input levels, the volume is controlled analog 96. At higher levels the volume is controlled digitally 98. This kind of control has the advantage of a lower noise level at low volumes. The reference numeral 94 indicates the level below the working level of the DRC.

It is clear that an artisan can extend the present invention with an increased number of thresholds and e.g. an increased number of time parameters.

It is further clear that the number of electro acoustic transducers is not restricted. Also being described only for one, the invention can be applied for one, two (stereo), three, four (Quattro), five (‘Dolby surround™’) or more loudspeakers or electro acoustic transducers. Another advantage provided by the present invention resides in the protection of the amplifier stage if no headset or transducer is detected. The present invention can be used to reduce the output power if no (external) transducer is detected to prevent an overheating of the output amplifier stage.

It is further clear that the present invention can be applied to all transducers in parallel controlling the “master volume”. It may be noted that the present invention can also be applied to any channel independently, preventing that the “weakest” transducers limits power output of the whole audio system.

The invention enables high quality and high volume output for headset and loudspeaker in music devices.

Electro acoustic transducer and time dependent maximum output level for audio amplifiers and thermal limitation and mechanical protection for the electro acoustic transducer using dynamic compression to increase the power and loudness capacity, reduce the unused power headroom and limit the maximum loudness for safety requirements.

The present invention provides the following advantages:

A defined maximum output level with optimized matching to the electro acoustic transducer connected.

The invention provides a maximum utilization of the full capacity and loudness of the electro acoustic transducers without the risk of damaging the transducers.

A defined maximum output level for safety requirements for the user in regard of protection of a user against noise and excessively loud headsets.

This application contains the description of implementations and embodiments of the present invention with the help of examples. It will be appreciated by a person skilled in the art that the present invention is not restricted to details of the embodiments presented above, and that the invention can also be implemented in another form without deviating from the characteristics of the invention. The embodiments presented above should be considered illustrative, but not restricting. Thus, the possibilities of implementing and using the invention are only restricted by the enclosed claims. Consequently, various options of implementing the invention as determined by the claims, including equivalent implementations, also belong to the scope of the invention.

1. Method for operating a dynamic range power control of an audio signal, with an adaptive threshold, wherein said dynamic range control comprises an audio signal input, an audio signal output and a power control comprising:
receiving at least two thresholds comprising a maximum power level for short time interval operation and a maximum power level for long time operation of an electro acoustic transducer,
detecting the power of the audio signal input continuously,
short term controlling the power of the audio signal output in a way that the power of the output is reduced to said maximum power level for short time operation, if the detected power of said audio signal input exceeds said maximum power level for short time interval operation, and
long term controlling the power of the audio signal output in a way that the power of the output signal is reduced to said maximum power level for long time operation, if the detected power of said audio signal input is exceeding said maximum power level for long time operation, for a predetermined time period, wherein said long term control overrides said short term control.

2. Method according to claim 1, characterized in that the speed said long term controlling of the power of the signal is performed depending from the difference power between said detected input signal and said maximum power level for long time operation.

3. Method according to any of the preceding claims, characterized in that said thresholds are received from said electro acoustic transducer.

4. Method according to any of the preceding claims, characterized in that said long term control comprises a smooth reduction of said output power level.

5. Method according to any of the preceding claims, characterized in that said long term control comprises a time interval controlled smooth reduction of said output power level.

6. Method according to any of the preceding claims, characterized in that said short term control comprises an immediate reduction of said output power level.

7. Method according to any of the preceding claims, wherein said power control comprises a digital power control having a digital control range and an analog power control having an analog power control range, characterized in that said signal volume is controlled analogously at signal levels lower than the control range of said analog control, and in that said signal power is controlled digitally at signal levels higher than the control range of said digital control, wherein the power control ranges of said analog and digital controls are not overlapping.

8. Computer program product comprising program code means stored on a computer readable medium for carrying out the method of anyone of claims 1 to 7, when said program product is run on an electronic audio device.

9. Computer program product comprising program code, downloadable from a server for carrying out the method of anyone of claims 1 to 7, when said program product is run on an electronic audio device.

10. Computer data signal embodied in a carrier wave and representing a program that instructs a computer to perform the steps of the method of anyone of claims 1 to 7.

11. Dynamic range controller with an adaptive threshold comprising:
an audio signal input,
an audio signal output,
means to continuously detect the power of the audio signal and
a power controller, said dynamic range control being characterized by:
means to receive at least two thresholds comprising a maximum power level for short time interval operation and a maximum power level for long time operation of an electro acoustic transducer,
wherein said dynamic range controller is configured to short term control the power of the audio signal output in a way that the power of the output is reduced to said maximum power level for short time operation, if the detected power of said audio signal input exceeds said maximum power level for short time interval operation, and
is configured to long term control the power of the audio signal output in a way that the power of the output signal is reduced to said maximum power level for long time operation, if the detected power of said audio signal input is exceeding said maximum power level for long time operation for a predetermined time period, wherein said long term control overrides said short term control.

12. Dynamic range control according to claim 11, further comprising a soft switch to slowly control the power of the signal in a way that the power of the output signal substantially equals said maximum power level.

13. Dynamic range control according to claim 11 or 12, further comprising a timer element to operate said long term control in a timer controlled way.

14. Electronic audio device comprising an audio signal source and an audio output characterized by a dynamic range controller with an adaptive threshold according to anyone of claims 11 to 13.

15. Electronic audio device according to claim 14, characterized in that said audio source is a digital audio signal source and said audio output is an analog audio output.

16. Electronic audio device according to claim 14, or 15 wherein the means to receive at least two thresholds comprised in the dynamic range control with an adaptive threshold is implemented by an integrated circuit implemented in a connector of said electro acoustic transducer.
